(19) United States
(12) Patent Application Publication
(10) Pub. No.: US 2007/0207564 A1
(43) Pub. Date: Sep. 6, 2007

(54) Method for manufacturing a semiconductor device

(75) Inventors: Yoji Nomura, Mizuho-shi (JP); Tetsuya Yamada, Gifu-shi (JP)

Correspondence Address: OLIFF & BERRIDGE, PLC, P.O. BOX 19928, ALEXANDRIA, VA, 22320, US

(73) Assignee: SANYO ELECTRIC CO., LTD., OSAKA (JP)

(21) Appl. No.: 11/709,774

(22) Filed: Feb. 23, 2007

(30) Foreign Application Priority Data
Mar. 6, 2006 (JP) 2006-059160

(51) Int. Cl. H01L 21/00

(52) U.S. Cl. 438/57; 257/E21.293

(57) ABSTRACT

A step for etching a wiring-structure layer and the like on a light-receiving part of a light detector and forming an apertured part is simplified. A silicon nitride film 86 is formed on a semiconductor substrate 60 by CVD or the like, and a layered structure 88 that has the wiring-structure layer is then formed. A photoresist film 122 having an aperture above the light-receiving part is formed on the layered structure 88, and the layered structure 88 is etched using the photoresist layer as an etching mask. The type of etching and the conditions under which the etching is performed are such that the etching selectivity of the interlayer insulating film with respect to a silicon nitride film will be maintained. In the etching process, the silicon nitride film 86 functions as an etching stopper. The silicon nitride film 86 that has been exposed at a bottom part of the apertured part 116 constitutes an antireflective film.

### CROSS-REFERENCE TO RELATED APPLICATION

The priority application number JP2006-059160 upon which this patent application is based is hereby incorporated by the reference.

### FIELD OF THE INVENTION

The present invention relates to a method for manufacturing a semiconductor device in which light-receiving elements are positioned on a semiconductor substrate; and in particular relates to a method for etching layers on a semiconductor substrate and forming an apertured part.

### DESCRIPTION OF THE RELATED ART

In recent years, optical disks such as CDs (Compact disks) and DVDs (Digital versatile disks) have come to occupy an important position as information recording media. In devices for reading these optical disks, laser light is emitted along tracks on the optical disk, and the light reflected is detected by an optical pickup mechanism. Recorded data is then read based on changes in the intensity of the reflected light.

Since the data rate for reading from optical disks is extremely high, the light detector for detecting the reflected light is composed of a semiconductor device that uses a PIN photodiode having a high response rate. The weak photoelectric conversion signal generated by the light-receiving part of the semiconductor device is amplified by an amplifier and then output to a subsequent signal-processing circuit. The length of wiring between the light-receiving part and amplifier is therefore reduced as much as possible in order to maintain the frequency characteristics of the photoelectric conversion signal and to minimize the superposition of noise. The light-receiving part and the circuit part, including the amplifier and the like, are preferably formed on the same semiconductor chip because of these issues and also from the standpoint of reducing the cost of manufacturing the light detector.

FIG. 1 is a schematic cross-sectional view of the vicinity of a light detector in which the light-receiving part and the circuit part are positioned adjoining one another on the same semiconductor substrate. A PIN-photodiode (PD) 8 is formed as a light-receiving element on a semiconductor substrate 2 in a region that corresponds to a light-receiving part 4. Transistors and other circuit elements are formed in a region corresponding to a circuit part 6.

The light detector of FIG. 1 has a two-layered wiring structure. An interlayer insulating film 12, wiring layers 14 and light-blocking layer 16 (both of which are composed of aluminum (Al)), and a silicon oxide film 18 and silicon nitride film 20 are layered as a layered structure 10 on the semiconductor substrate 2. The interlayer insulating film 12 is formed using SOG (spin on glass), BPSG (borophosphosilicate glass), or TEOS (tetra-ethoxy-silane). The silicon nitride film 20 and the silicon oxide film 18 together constitute a protective layer for the layers situated there bellow.

The layered structure 10 is also formed on the semiconductor substrate 2 of the light-receiving part 4. The layered structure 10 is preferably removed in order to increase the efficiency of light incidence on the semiconductor substrate 2 of the light-receiving part 4. The layered structure 10 remains on the surrounding circuit part 6 and etching is selectively performed on the light-receiving part 4 to form an apertured part 22 on the layered structure 10 on the light-receiving part 4.

Etching therefore cannot proceed uniformly in the plane of the apertured part because the layered structure 10 will not necessarily be flat, the etching rate will be adversely affected in the plane of the apertured part, and the like.

A polysilicon film is formed below the layered structure 10 and the apertured part is etched using the polysilicon film as an etching stopper in order to resolve this problem. The use of an etching stopper will enable a uniform etching depth to be more readily produced in the plane of the apertured part.

When the polysilicon film used as the etching stopper is also positioned on the circuit part 6, the polysilicon film will be situated between the Al wiring and semiconductor substrate when the Al wiring makes contact with the semiconductor substrate, which is undesirable. For this reason the polysilicon film is selectively formed on the light-receiving part 4.

FIGS. 2A through 2D are schematic views used to describe a conventional method for manufacturing a light detector in which the polysilicon film is formed at a position of the light-receiving part 4 and then an apertured part is formed, and that show schematic cross-sectional views of the vicinity of the light-receiving part 4 during the main steps. FIG. 2A is a cross-sectional view of a point at which the layered structure 10 has been formed on the semiconductor substrate 2 and shows the structure before the apertured part 22 has been formed. A silicon oxide film 30 is formed on the semiconductor substrate 2 upon which the PIN photodiode, transistors, and other elements are formed. Polysilicon is then deposited on the surface of the silicon oxide film, the polysilicon film is patterned by a photolithography technique, and a polysilicon pad 32 is formed in a region that corresponds to the light-receiving part 4. The layered structure 10 is formed on the polysilicon pad.

A photoresist is then applied on the layered structure 10, the photoresist is patterned using a photolithography technique, and a photoresist film 34 is formed that has an aperture at a position that corresponds to the light-receiving part 4 (FIG. 2B).

The layered structure 10 is removed by etching using the photoresist film 34 as an etching mask, and the apertured part 22 is formed at a position that corresponds to the light-receiving part 4. The polysilicon pad 32 functions as an etching stopper during this etching, and the polysilicon pad 32 is exposed at a bottom surface of the apertured part 22 (FIG. 2C). A different etchant is then used to etch off the polysilicon. The apertured part 22 is hollowed out down to an upper surface of the silicon oxide film 30 (FIG. 2D).

In the process for forming the apertured part 22, a photolithography step is needed to form the polysilicon pad 32 from the polysilicon film layered on the silicon oxide film 30. In addition, after the step of etching the interlayer insulating film 12 on the polysilicon pad with the polysilicon pad 32 acting as an etching stopper, a step of etching the polysilicon pad 32 using a different etchant is necessary. Furthermore, after the apertured part 22 has been formed, a step can be necessary for depositing the antireflective film on the bottom surface of the apertured part. Therefore, the process for forming the apertured part 22 using the polysilicon pad 32 as an etching stopper has a large number of steps.

### SUMMARY OF THE INVENTION

The present invention provides a method for manufacturing a semiconductor device wherein an apertured part that corresponds to a light-receiving part can be formed in fewer steps.

The present invention provides a method for manufacturing a semiconductor device having a light-receiving part formed on a semiconductor substrate and an apertured part provided to a structure layer on the substrate corresponding to a position of the light-receiving part; the method for manufacturing a semiconductor device comprising the steps of layering a base film in which a base film that is resistant to corrosion in the etching process used to form the apertured part is layered on the semiconductor substrate; layering a structure layer in which the structure layer on the substrate is layered on a surface of the base film; and forming an apertured part in which the structure layer on the substrate is etched using the base film as an etching stopper, and the apertured part is formed.

### BRIEF DESCRIPTION OF THE DRAWINGS

FIG. 1 is a schematic cross-sectional view showing structures of a light-receiving part and circuit part of a conventional light detector;

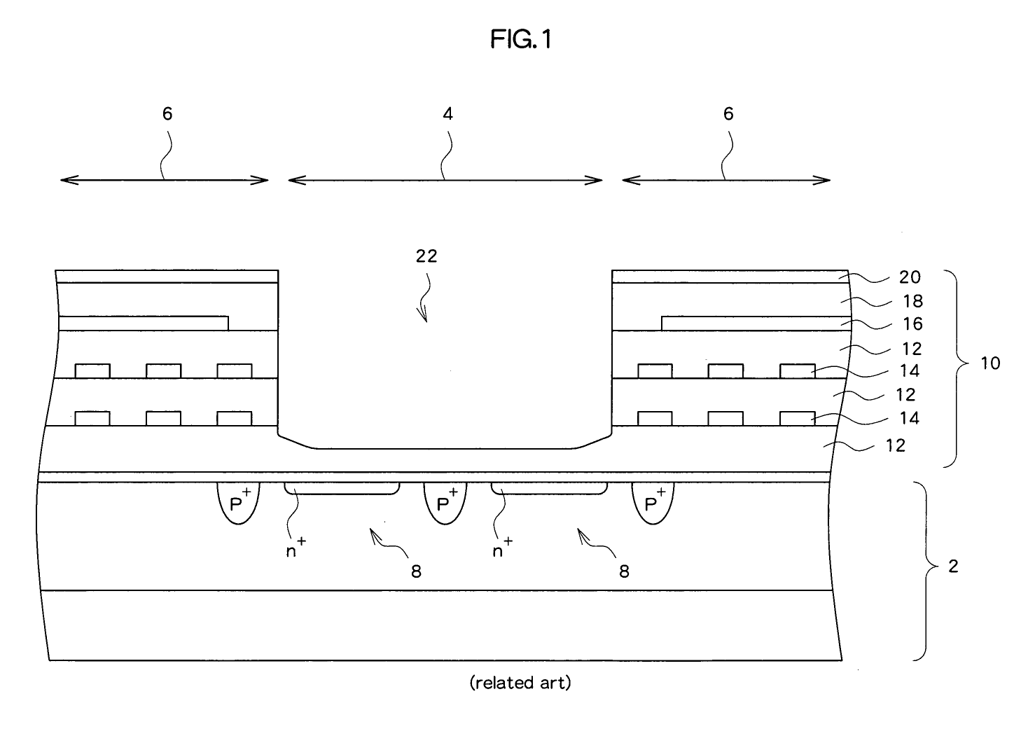

FIGS. 2A through 2D are schematic views showing cross-sectional structures of the conventional light detector during major steps of forming an apertured part;

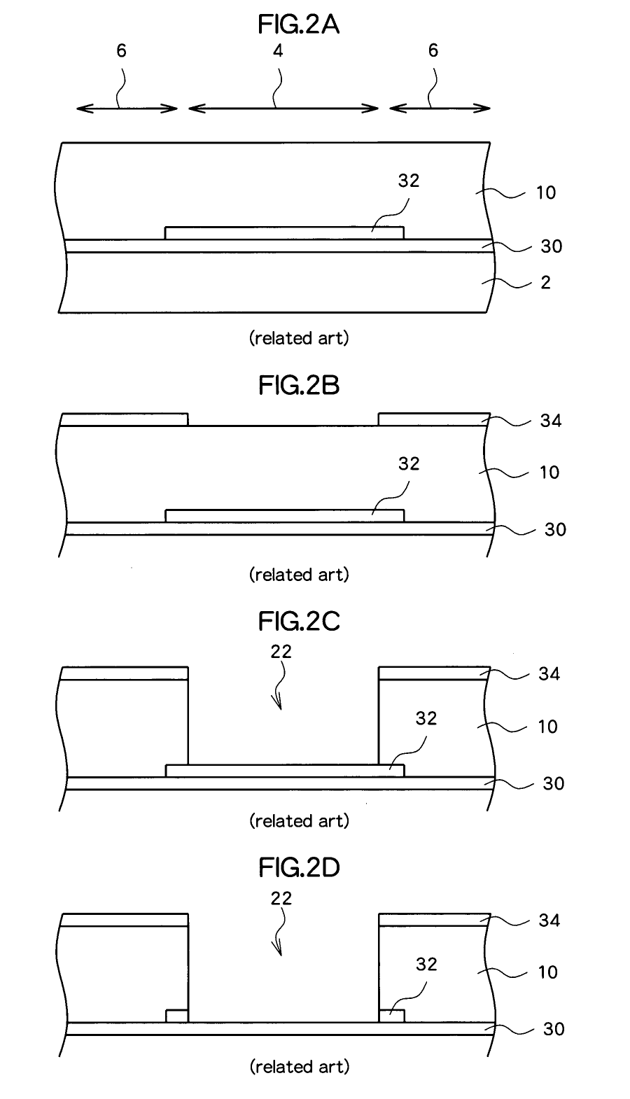

FIG. 3 is a schematic plan view of a semiconductor device that is a light detector according to an embodiment of the present invention;

FIG. 4 is a schematic cross-sectional view showing structures of a light-receiving part and a circuit part of the light detector that is an embodiment of the present invention; and

FIGS. 5A through 5D are schematic views showing cross-sectional structures of the light detector of an embodiment of the present invention during major steps for forming an apertured part.

### DESCRIPTION OF THE PREFERRED EMBODIMENTS

An embodiment of the present invention shall be described below with reference to the drawings.

The embodiment is a light detector for mounting on a light-pickup mechanism of an apparatus for reading optical disks such as CDs and DVDs.

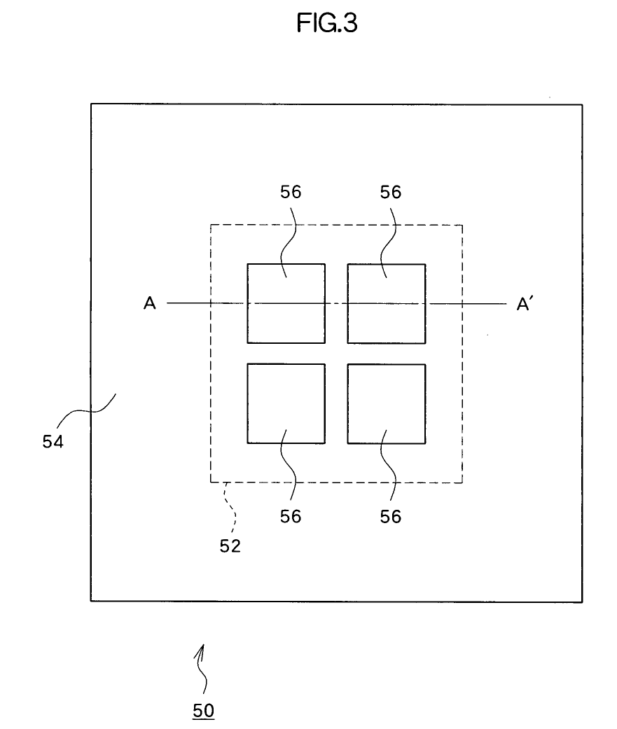

FIG. 3 is a schematic plan view of a semiconductor device that acts as the light detector according to the present embodiment. This light detector 50 is formed on a silicon semiconductor substrate. The light detector 50 is composed of a light-receiving part 52 and a circuit part 54. The light-receiving part 52 comprises, e.g., four PIN photodiodes (PD) 56 in a 2×2 arrangement, and in four partitioned segments receives light incident on the surface of the substrate from an optical system. The circuit part 54 is positioned, e.g., around the light-receiving part 52. Transistors, for example, and other circuit elements are formed on the circuit part 54. A circuit for amplifying output signals from the light-receiving part 52 and other signal-processing circuits can be formed on the same semiconductor chip as the light-receiving part 52 using the circuit elements of the circuit part 54. Wiring connected to the circuit elements and wiring connected to a diffusion layer constituting the light-receiving part 52 are positioned on the circuit part 54 (this wiring is not shown in FIG. 3). This wiring is formed by patterning the Al film layered on the semiconductor substrate.

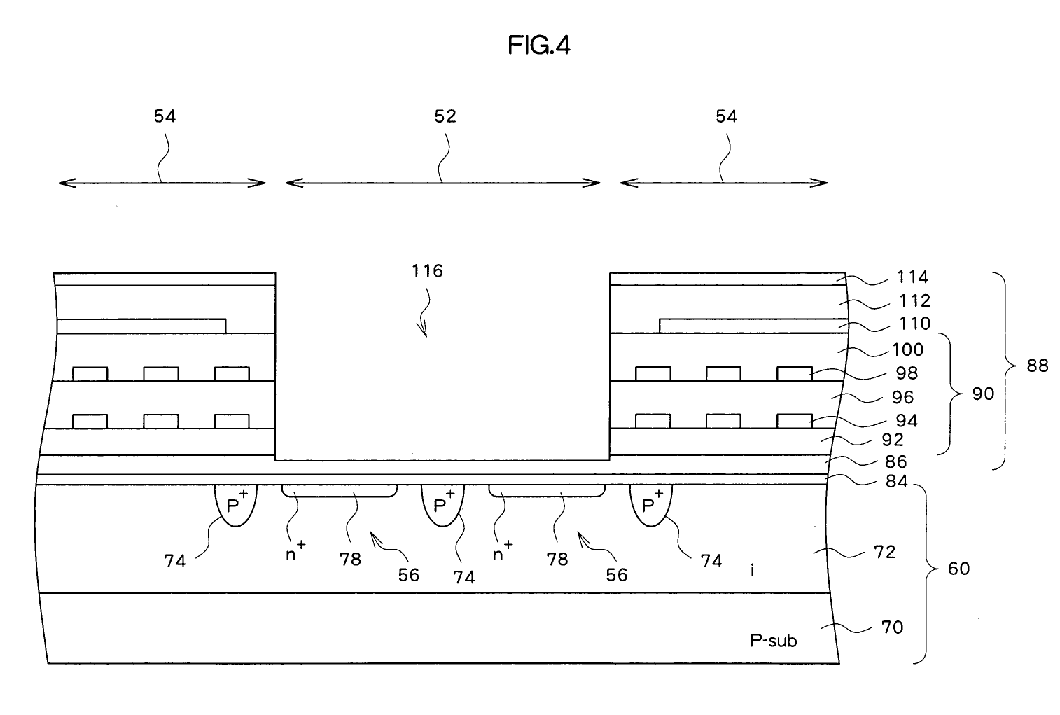

FIG. 4 is a schematic cross-sectional view showing the structure of the light-receiving part 52 and the circuit part 54 in a cross section perpendicular to the semiconductor substrate along the straight line A-A′ shown in FIG. 3.

The present light-receiving part 50 is produced using the semiconductor substrate 60, wherein an epitaxial layer 72 having a lower impurity concentration and a higher specific resistance than a P-sublayer 70 is built up on the P-sublayer 70, which is a p-type silicon substrate into which a p-type impurity has been introduced. The P-sublayer 70 constitutes a common anode for the PDs 56 and, for example, applies a grounding potential from a rear surface of the substrate. An isolated region 74 applies a grounding and constitutes a common anode with the P-sublayer 70.

In the light-receiving part 52, the epitaxial layer 72 constitutes an i layer of the PD 56, and the aforedescribed isolated region 74 and a cathode region 78 are formed on the surface of the epitaxial layer 72.

A silicon oxide film comprising a gate oxide film and a local oxide film (LOCOS) is formed on the surface of the semiconductor substrate 60. A gate electrode composed of the MOSFET or the like is formed on the gate oxide film using, e.g., polysilicon or tungsten (W). A silicon oxide film 84 is formed on the surface of the substrate and covers the gate electrode, and a silicon nitride film 86 is formed thereon.

Once the silicon nitride film 86 has been formed, a layered structure 88 is formed on the semiconductor substrate 60. The layered structure 88 has the wiring-structure layer 90 as a structure layer on the substrate, and also has the protective layer and the like layered on the wiring-structure layer 90. The wiring of the light detector 50 has a two-layer structure. A first interlayer insulating film 92, a first Al layer 94, a second interlayer insulating film 96, a second Al layer 98, and a third interlayer insulating film 100 are sequentially layered on the semiconductor substrate 60 as a wiring-structure layer 90. The first Al layer 94 and second Al layer 98 are patterned using photolithography techniques, and a wiring is formed on the circuit part 54. The interlayer insulating films are formed using SOG, BPSG, or TEOS.

An Al layer 110 for blocking light is layered on the wiring-structure layer of the circuit part 54, and a silicon oxide film 112 and a silicon nitride film 114 are further sequentially layered thereon as a protective layer.

An apertured part 116 is formed in a region that corresponds to the light-receiving part 52. The apertured part 116 is formed by etching the layered structure 88 that has the wiring-structure layer 90. The silicon nitride film 86 is exposed at the bottom of the apertured part 116. The apertured part 116 of the layered structure 90 is thus provided on the light-receiving part 52, whereby the transmittance of light to the PD 56 is improved, and the amplitude of a photoelectric conversion signal according to the reflected laser light can be maintained. In addition, the silicon nitride film 86 and silicon oxide film 84 at the bottom of the apertured part 116 constitute the antireflective film for incident light oriented toward the light-receiving part 52. The antireflective film further improves the efficiency of light incidence on the PD 56.

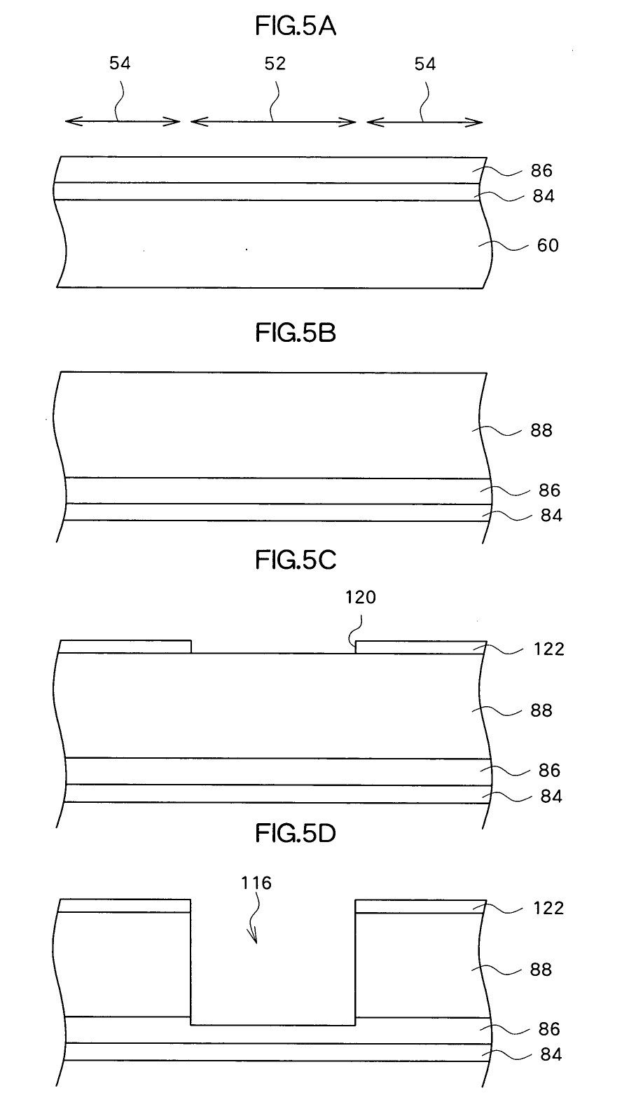

A method for manufacturing the light detector 50 shall be described next using FIGS. 5A through 5D. FIGS. 5A through 5D are schematic views for describing the method for forming the present light detector in which the apertured part 116 is formed corresponding to a location of the light-receiving part 52, and show schematic cross-sectional views of the vicinity of the light-receiving part 52 during the main steps.

First, the silicon oxide film 84 is formed on the aforementioned semiconductor substrate 60 upon which the PD 56, transistor, and other elements are formed (FIG. 5A). The silicon oxide film 84 is deposited and formed by, for example, CVD (chemical vapor deposition). The silicon nitride film 86 is formed on the silicon oxide film 84 by CVD or the like (FIG. 5A). The silicon nitride film 86 is used as an etching stopper in the aforedescribed manner, and is etched to a certain degree and made thinner. The thickness of the silicon nitride film 86 remaining after etching is set so as to form the antireflective film. In other words, the initial thickness of the silicon nitride film 86 during deposition can be set to be the sum of the thickness lost during etching and the thickness necessary to function as an antireflective film.

Once the silicon nitride film 86 has been deposited, the layered structure 88 is formed (FIG. 5B). The layers constituting the layered structure 88 can be layered using CVD or PVD (physical vapor deposition).

The Al layers of the layers constituting the layered structure 88 are patterned and removed from the top of the light-receiving part 52. For this reason, the wiring-structure layer 90 of the layered structure 88 layered on the surface of the silicon nitride film 86 has only the interlayer insulating films 92, 96, 100 on the light-receiving part 52. The silicon oxide film 112 and silicon nitride film 114 are layered on the layered structure on the light-receiving part 52.

A photoresist film is formed on the layered structure 88 and the photoresist film is patterned by photolithography techniques to form a photoresist film 122 having an aperture 120 at a position that corresponds to the light-receiving part 52 (FIG. 5C).

An etching process is performed on the layered structure 88 using the photoresist film 122 as an etching mask, and an apertured part 116 is formed (FIG. 5D). The etching can be performed anisotropically using, e.g., a dry etching method. In addition, the type of etching and the conditions under which etching is performed are such that the etching selectivity of the interlayer insulating films with respect to the silicon nitride film will be maintained. The silicon nitride film 86 functions as an etching stopper in the etching process. Accordingly, the etching process is continued for a short time after the surface of the silicon nitride film 86 has been reached to allow the interlayer insulating film of the wiring-structure layer 90 to be cleanly removed from the bottom surface of the apertured part 116. At this time, the silicon nitride film 86 is reduced in thickness to a certain degree in accordance with the selectivity with the interlayer insulating film, as opposed to not being etched at all. However, as described above, the initial thickness of the silicon nitride film 86 is set when deposition is performed in anticipation of the loss in thickness so that, after being etched, the silicon nitride film 86 will have a thickness suitable for preventing reflection.

The thickness of a silicon nitride film 86 that is suitable as an antireflective film can be set in accordance with the wavelength of the laser light to be detected by the present light detector. For example, the laser light used for CDs and DVDs has wavelengths in the 780-nm and 650-nm bands. The thickness of the silicon nitride film 86 is set to a value that corresponds to, e.g., ¼ of the wavelength of the laser light, whereby the antireflective effect is obtained. In the configuration in which the silicon nitride film 86 and silicon oxide film 84 are layered on the PD 56 as shown in FIG. 4, the two films work together to achieve an antireflective function. In this instance, a suitable thickness of the silicon nitride film 86 can be set using the index of refraction of the silicon nitride film 86 and the index of refraction and thickness of the silicon oxide film 84 in addition to the wavelength of the reflected light.

The etching process is performed using the silicon nitride film 86 as an etching stopper, whereby it is possible to etch from the surface of the layered structure 88 to the silicon nitride film 86 in a single process and form the aperture part 116. For example, the manufacturing method may also have a separate etching process in which the silicon nitride film 114 positioned as an upper layer of the layered structure 88 is quickly removed. In this instance as well, the removal of the lower layer of the layered structure 88 including at least the wiring-structure layer 90 and the etching down to the silicon nitride film 86, which is the antireflective film, can be performed in a single process. In other words, the apertured part 116 can be formed in fewer steps than in the conventional technique in which, after the wiring-structure layer 90 has been removed, a separate etching process is performed to remove the polysilicon pad 32. Even in instances in which the silicon nitride film 114 and the layers below the silicon nitride film are etched in separate etching processes, the photoresist film 122 can be used as a common etching mask in both etching processes.

Once the etching formation of the apertured part 116 is complete, the photoresist film 122 is removed. Accordingly, the basic structure of the present light detector 50 shown in FIG. 4 is formed.

As described above in the embodiment, the present invention provides a method for manufacturing a semiconductor device having a light-receiving part formed on a semiconductor substrate and an apertured part provided to a structure layer on the substrate corresponding to a position of the light-receiving part; the method for manufacturing a semiconductor device comprising the steps of layering a base film in which a base film that is resistant to corrosion in the etching process used to form the apertured part is layered on the semiconductor substrate; layering a structure layer in which the structure layer on the substrate is layered on a surface of the base film; and forming an apertured part in which the structure layer on the substrate is etched using the base film as an etching stopper, and the apertured part is formed.

The method for manufacturing a semiconductor device according to the present invention can be applied to, e.g., a semiconductor device wherein the structure layer on the substrate is a wiring-structure layer in which a wiring and an interlayer insulating film have been layered.

In addition, the method for manufacturing a semiconductor device according to the present invention can be applied to, e.g., a semiconductor device in which the base film is a silicon nitride film.

In the method for manufacturing a semiconductor substrate according to the present invention, the thickness of the base film layered in the step of layering a base layer can be set on the basis of the sum of the thickness of the base film etched in the step of forming an apertured part and the thickness of an antireflective film for light incident on the light-receiving part.

According to the present invention, steps of patterning the etching stopper used when the apertured part is provided to the structure layer on the substrate composed of the wiring-structure layer and the like layered on the light-receiving part, and of etching the etching stopper, which is a separate step from etching back the structure layer on the substrate, are rendered unnecessary.

What is claimed is:

1. A method for manufacturing a semiconductor device having a light-receiving part formed on a semiconductor substrate and an apertured part provided to a structure layer on the substrate corresponding to a position of the light-receiving part; the method for manufacturing a semiconductor device comprising the steps of:
layering a base film in which a base film that is resistant to corrosion in the etching process used to form the apertured part is layered on the semiconductor substrate;
layering a structure layer in which the structure layer on the substrate is layered on a surface of the base film; and
forming an apertured part in which the structure layer on the substrate is etched using the base film as an etching stopper, and the apertured part is formed.

2. The method for manufacturing a semiconductor device of claim 1, wherein
the structure layer on the substrate is a wiring-structure layer in which a wiring and an interlayer insulating film are layered.

3. The method for manufacturing a semiconductor device of claim 1, wherein
the base film is a silicon nitride film.

4. The method for manufacturing a semiconductor device of claim 1, wherein
the thickness of the base film layered in the step of layering the base film is set on the basis of the sum of the thickness of the base film etched in the step of forming the apertured part and the thickness of an antireflective film for light incident on the light-receiving part.
